(19) United States
(12) Patent Application Publication
(10) Pub. No.: US 2024/0355700 A1
(43) Pub. Date: Oct. 24, 2024

(54) DIE-PACKAGE INTERCONNECT TO FACILITATE THERMAL CONDUCTION

(71) Applicant: TEXAS INSTRUMENTS INCORPORATED, Dallas, TX (US)

(72) Inventors: Siraj Akhtar, Richardson, TX (US); Enis Tuncer, Dallas, TX (US); Hiep Xuan Nguyen, Cedar Hill, TX (US)

(21) Appl. No.: 18/458,367

(22) Filed: Aug. 30, 2023

Related U.S. Application Data
(60) Provisional application No. 63/496,718, filed on Apr. 18, 2023.

(51) Int. Cl. H01L 23/367; H01L 21/306; H01L 21/3065; H01L 21/308; H01L 23/00

(52) U.S. Cl. CPC H01L 23/367; H01L 21/30608; H01L 21/3065; H01L 21/308; H01L 24/16; H01L 24/32; H01L 24/73; H01L 2224/16059; H01L 2224/16245; H01L 2224/32245; H01L 2224/73203; H01L 2224/73253; H01L 2924/182

(57) ABSTRACT

The present disclosure generally relates to die-package interconnect in a semiconductor device assembly to facilitate thermal conduction. In an example, a semiconductor device assembly includes a semiconductor substrate, a metallization structure, a package substrate, a die-package interconnect, and one or more insulation layers. The metallization structure is on the semiconductor substrate and includes a first metal layer. The die-package interconnect is between the metallization structure and a second metal layer of the package substrate. The die-package interconnect overlaps at least part of a transistor on the semiconductor substrate. The insulation layer(s) are on the metallization structure and have a first portion having a first thickness and a second portion having a second thickness. The first portion is outside a footprint of the transistor. The second portion is between the die-package interconnect and the at least part of the transistor. The first thickness being larger than the second thickness.

### CROSS-REFERENCE TO RELATED APPLICATIONS

This application claims priority to and the benefit of U.S. Provisional Patent Application Ser. No. 63/496,718, filed on Apr. 18, 2023, which is incorporated herein by reference in its entirety.

### BACKGROUND

A die, which may in some instances be an integrated circuit (IC) die, is commonly packaged and incorporated into a larger electronic device. The package may include interconnects to allow transmission of electrical signals between the die and components external to the die, such as a printed circuit board (PCB). The package may also include components that provide a level of physical protection to the die and other components, such as an underfill and molding compound. Some dies may generate a large amount of thermal energy during operations. It is desirable to facilitate removal of the thermal energy from the dies through their packages to avoid excessive thermal energy, which may otherwise interfere with the dies' operations or even damage the dies.

### SUMMARY

This Summary is provided to introduce a brief selection of disclosed concepts in a simplified form that are further described below in the Detailed Description including the drawings provided. Various disclosed devices and methods may be beneficially applied to a die-package interconnect to facilitate thermal conduction. While such embodiments may be expected to achieve a more direct path from a die to a package substrate for thermal conduction, no particular result is a requirement unless explicitly recited in a particular claim.

An example described herein is a semiconductor device assembly. The semiconductor device assembly includes a semiconductor substrate, a metallization structure, a package substrate, a die-package interconnect, and one or more insulation layers. The semiconductor substrate includes a transistor. The metallization structure is on the semiconductor substrate and includes a first metal layer. The package substrate has a second metal layer. The die-package interconnect is between the metallization structure and the second metal layer. The die-package interconnect overlaps at least part of the transistor. The one or more insulation layers are on the metallization structure. The one or more insulation layers have a first portion having a first thickness and a second portion having a second thickness. The first portion is outside a footprint of the transistor. The second portion is between the die-package interconnect and the at least part of the transistor. The first thickness being larger than the second thickness.

Another example is a method. A die is provided. The die includes a semiconductor substrate and a metallization structure. The semiconductor substrate includes a transistor. The metallization structure is on the semiconductor substrate and includes a metal layer. A die-package interconnect is formed on the die. The die-package interconnect is on a side of the metallization structure distal from the semiconductor substrate. The die-package interconnect overlaps at least part of the transistor.

A further example described herein is an apparatus. The apparatus includes a packaged semiconductor device and a heat sink. The packaged semiconductor device includes a semiconductor substrate, a metallization structure, a package substrate, a die-package interconnect, one or more insulation layers, and a molding compound. The semiconductor substrate includes a transistor. The metallization structure is on the semiconductor substrate and includes a first metal layer. The package substrate has a second metal layer. The die-package interconnect is between the metallization structure and the second metal layer. The die-package interconnect overlaps at least part of the transistor. The one or more insulation layers are on the metallization structure. The one or more insulation layers have a first portion having a first thickness and a second portion having a second thickness. The first portion is outside the footprint of the transistor. The second portion is between the die-package interconnect and the at least part of the transistor. The first thickness is larger than the second thickness. The molding compound encapsulates the semiconductor substrate, the metallization structure, the die-package interconnect, the one or more insulation layers, and at least part of the package substrate. The heat sink is on a side of the molding compound opposite from the package substrate.

The foregoing summary outlines rather broadly various features of examples of the present disclosure in order that the following detailed description may be better understood. Additional features and advantages of such examples will be described hereinafter. The described examples may be readily utilized as a basis for modifying or designing other examples that are within the scope of the appended claims.

### BRIEF DESCRIPTION OF THE DRAWINGS

FIG. 1 is a schematic illustrating a cross-sectional view of a semiconductor device assembly having a die-package interconnect to facilitate thermal conduction according to some examples.

FIG. 2 is a schematic illustrating a cross-sectional view of a semiconductor device assembly having another die-package interconnect according to some examples.

FIG. 3 is a schematic illustrating a cross-sectional view of a semiconductor device assembly having yet another die-package interconnect according to some examples.

FIGS. 4, 5, 6, 7, 8, and 9 are schematics illustrating layout views of dies having die-package interconnects to facilitate thermal conduction according to some examples.

FIG. 10 is a flow chart of a method 1000 of manufacturing the semiconductor device assemblies of FIGS. 1, 2, and 3 according to some examples.

FIGS. 11A, 11B, 12A, 12B, 13A, 13B, 14, 15A, 15B, and 16 illustrate a method of manufacturing the semiconductor device assembly of FIG. 1 according to some examples.

FIGS. 17, 18, and 19 are schematics illustrating alignment of reticle masks for fabricating die-package interconnects for the semiconductor device assembly of FIG. 2 according to some examples.

FIGS. 20, 21, and 22 are schematics illustrating alignment of reticle masks for fabricating die-package interconnects for the semiconductor device assembly of FIG. 3 according to some examples.

The drawings, and accompanying detailed description, are provided for understanding of features of various examples and do not limit the scope of the appended claims. The examples illustrated in the drawings and described in the accompanying detailed description may be readily utilized as a basis for modifying or designing other examples that are within the scope of the appended claims. Identical reference numerals may be used, where possible, to designate identical elements that are common among drawings. The figures are drawn to clearly illustrate the relevant elements or features and are not necessarily drawn to scale.

### DETAILED DESCRIPTION

Various features are described hereinafter with reference to the figures. An illustrated example may not have all the aspects or advantages shown. An aspect or an advantage described in conjunction with a particular example is not necessarily limited to that example and can be practiced in any other examples even if not so illustrated or if not so explicitly described. Further, methods described herein may be described in a particular order of operations, but other methods according to other examples may be implemented in various other orders (e.g., including different serial or parallel performance of various operations) with more or fewer operations.

The present disclosure relates to a die-package interconnect in a semiconductor device assembly to facilitate thermal conduction. Some examples include a semiconductor device assembly including a die and a package substrate. The die includes a semiconductor substrate including a transistor or other device. The die also includes a metallization structure on the semiconductor substrate and includes a metal layer. A package substrate (e.g., a lead frame) has a second metal layer. A die-package interconnect is between the metallization structure and the second metal layer. The die-package interconnect overlaps at least part of the transistor. Various examples herein illustrate configurations of a die-package interconnect. In such configurations, a more direct thermal conduction path to the package substrate may be formed, which may permit more efficient thermal conduction away from the semiconductor substrate. Efficient thermal conduction may particularly be beneficial for, for example, a high electron mobility transistor (HEMT) operating on a group III-group V (III-V) platform, such as a gallium nitride (GaN) platform) on the semiconductor substrate, which may have a high thermal density and may generate relatively high thermal energy. Other benefits and advantages may be achieved.

Various examples are described herein. Although the specific examples may illustrate various aspects of the above generally described features, examples may incorporate any combination of the above generally described features (which are described in more detail in examples below). Three-dimensional x-y-z axes are illustrated in some figures for ease of reference. Some cross-sectional views of various apparatuses or dies herein may be general depictions to communicate various aspects or concepts concerning such apparatuses or dies.

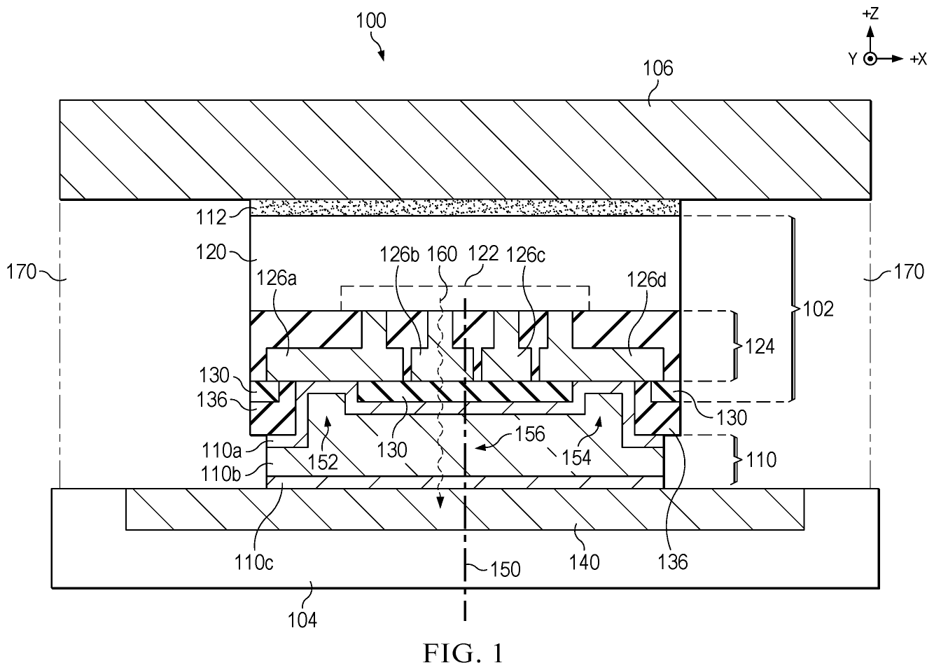

FIG. 1 illustrates a cross-sectional view of a semiconductor device assembly 100 according to some examples. The semiconductor device assembly 100 includes a die 102, a package substrate 104, and a heat spreader 106. In some examples, die 102 and package substrate 104 can be part of a packaged assembly, and heat spreader 106 is external to the packaged assembly. In some examples, die 102, package substrate 104, and heat spreader 106 can be part of a packaged assembly. The die 102 is attached at the front side of the die 102 to the package substrate 104. The die 102 is attached to the package substrate 104 by, among other things, a die-package interconnect 110. The die 102 and package substrate 104 may be in a flip chip (FC) configuration. The die 102 is attached at the back side of the die 102 to the heat spreader 106. The die 102 is attached to the heat spreader 106 by, among other things, a backside structure 112, which may include thermal grease, an adhesive, a metal layer (e.g., patterned or unpatterned), solder, a lid, or any combination thereof.

The die 102 includes a semiconductor substrate 120. The semiconductor substrate 120 may be or include bulk semiconductor substrate, a semiconductor-on-insulator (SOI) substrate, or any other appropriate substrate. The semiconductor substrate 120 may include one or more epitaxial layers on, e.g., the bulk semiconductor substrate, SOI substrate, or other substrate. An epitaxial layer may be or include silicon (Si), silicon germanium (SiGe), gallium arsenide (GaAs), gallium nitride (GaN), aluminum gallium nitride (AlGaN), aluminum nitride (AlN), a III-V semiconductor material, the like, or a combination thereof. In some examples, the semiconductor substrate 120 is or includes a silicon or silicon carbide substrate (which may be singulated from a bulk silicon or silicon carbide wafer at the conclusion of semiconductor processing). The semiconductor substrate 120 has a front side surface in and/or on which a device(s) 122 (e.g., transistor(s)) are formed. The device(s) 122 may be or include any device, such as a planar or fin metal-oxide semiconductor (MOS) transistor, a HEMT, a bipolar junction transistor (BJT), a diode, or another device. The device(s) 122 are formed in one or more active areas on the semiconductor substrate 120. The active area(s) may be the areas on the semiconductor substrate 120 where a majority of the thermal energy generated on the die 102 is generated during operation. For example, for a field effect transistor (FET), an active area may include a source region, a drain region, and a channel region between the source region and the drain region.

The die 102 also includes a metallization structure 124 on the semiconductor substrate 120. The metallization structure 124 includes one or more insulation layers (e.g., inter-layer dielectric (ILD) layer(s) and/or inter-metallization dielectric (IMD) layer(s)) and one or more metallization layers. As illustrated for simplicity, an uppermost metallization layer is shown in the metallization structure 124. The uppermost metallization layer is a metallization layer in the metallization structure 124 that is most distal from the semiconductor substrate 120 relative to other metallization layer(s) in the metallization structure 124. The uppermost metallization layer, as illustrated, includes a metal layer 126a, a metal layer 126b, a metal layer 126c, and a metal layer 126d. The metallization layer(s) of the metallization structure 124 may be electrically coupled to the device(s) 122 on the semiconductor substrate 120. For example, assuming the device 122 is a transistor (e.g., a HEMT), a source terminal of the transistor may be electrically coupled to the metal layer 126a (which may be through other metal layers and metal vias in other metallization layers); a gate terminal of the transistor may be electrically coupled to the metal layer 126b (which may be through other metal layers and metal vias in other metallization layers); and a drain terminal of the transistor may be electrically coupled to the metal layer 126c (which may be through other metal layers and metal vias in other metallization layers).

The die 102 includes a first insulation layer 130 on the metallization structure 124 distal from the semiconductor substrate 120. The first insulation layer 130 may be or include at least one of an oxide layer or a nitride layer. For example, the first insulation layer 130 may be a protective overcoat (PO) layer including silicon oxide (SiO₂), silicon nitride (Si₃N₄ or SiN), silicon oxynitride (SiON), or the like. In an example, the first insulation layer 130 includes a tetraethyl orthosilicate (TEOS) silicon oxide layer and/or a silicon nitride layer. The first insulation layer 130 may be a protective layer. The first insulation layer 130 has openings therethrough for access to the uppermost metallization layer, such as to the metal layers 126a, 126d in the illustrated example.

In some examples, the semiconductor device assembly 100 includes a second insulation layer 136 on the first insulation layer 130, such as in a region outside the footprint of device 122. The second insulation layer 136 may be a stress buffer layer on the die 102. The second insulation layer 136 may also provide mechanical support to the die-package interconnect 110 and provide additional electrical insulation between die-package interconnect 110 and other die-package interconnects (not shown in FIG. 1). The second insulation layer 136 may be or include polyimide (PI), polybenzoxazole (PBO), benzocyclobutene (BCB), or the like, and may have lower thermal conductivity than the first insulation layer 130. The second insulation layer 136 has an opening therethrough for access to the uppermost metallization layer (e.g., through the openings through the first insulation layer 130).

The package substrate 104 may be any appropriate package substrate. For example, the package substrate 104 may include metallization layers and insulation (e.g., resin) layers and/or may include a routable lead frame (RLF). In some examples, the package substrate 104 may be or include an embedded trace substrate (ETS). As illustrated, the package substrate 104 includes a metal layer 140.

The die-package interconnect 110 provides electrical connection between the metal layers 126a, 126d of the metallization structure 124 and the metal layer 140 of the package substrate 104. The die-package interconnect 110 can include a bump, a micro bump, a solder bump, a pillar bump, a stud bump, a solder ball, etc. Referring to FIG. 1, the die-package interconnect 110 includes an under bump metallization (UBM) 110a, a pillar or bump 110b (referred to as “bump 110b” for ease), and solder 110c. The UBM 110a is conformal along an outer surface of the second insulation layer 136, along sidewall surfaces of the opening through the second insulation layer 136, along surfaces of the metal layers 126a, 126b exposed through the openings through the first insulation layer 130 and the opening of the second insulation layer 136, and along sidewall surfaces and on a surface of the first insulation layer 130 exposed through the opening through the second insulation layer 136. The UBM 110a may be or include one or more layers of copper (Cu), nickel (Ni), aluminum (Al), titanium (Ti), an alloy thereof, or the like. The bump 110b is on the UBM 110a. The bump 110b may be or include solder (e.g., tin), copper, a copper alloy, or the like. The solder 110c is on the bump 110b and attaches and electrically couples to the metal layer 140 of the package substrate 104. Other types of die-package interconnects may be implemented in other examples.

The die-package interconnect 110 overlaps (e.g., vertically overlaps) the device 122 (e.g., transistor) in the active area on the semiconductor substrate 120. At least a portion of the die-package interconnect 110 intersects with a direction normal to the front side surface (e.g., a z-direction) of the semiconductor substrate 120 at the device 122 (e.g., at the active area). Axis 150 in FIG. 1 illustrates a direction normal to the front side surface at the device 122. The die-package interconnect 110 includes a first vertical portion 152, a second vertical portion 154, and a lateral portion 156. The first vertical portion 152 overlaps, contacts, and is electrically coupled to the metal layer 126a through the opening through the second insulation layer 136 and a respective opening through the first insulation layer 130. The second vertical portion 154 overlaps, contacts, and is electrically coupled to the metal layer 126d through the opening through the second insulation layer 136 and a respective opening through the first insulation layer 130. The lateral portion 156 extends between the first vertical portion 152 and the second vertical portion 154 and is on and contacts the first insulation layer 130 between the respective openings through the first insulation layer 130 that expose the metal layers 126a, 126d. The lateral portion 156 overlaps with the device 122 (e.g., transistor). The lateral portion 156 intersects the axis 150. As shown, no second insulation layer 136 is between at least some of the lateral portion 156 and the first insulation layer 130. The second insulation layer 136 abuts a lateral periphery (e.g., in both x and y-directions, in some examples) of the die-package interconnect 110. The illustrated die-package interconnect 110 may be referred to as a bridge die-package interconnect. The die-package interconnect 110 bridges between and is attached to at least two metal layers (e.g., metal layers 126a, 126d). The bridge die-package interconnect can have an elongated footprint (e.g., on the x-y plane), such as a rectangular footprint, an oval footprint, an oblong footprint, etc.

The device 122 in the active area on the semiconductor substrate 120 may be a thermal energy source in operation. While operating, the device 122 may conduct electrical current, which may generate thermal energy. This may be particularly pronounced where the device is a high voltage HEMT. The semiconductor device assembly 100 may provide for a more direct thermal conduction path 160 from the device 122 to the package substrate 104. With the die-package interconnect 110 (e.g., lateral portion 156) overlapping the device 122, the die-package interconnect 110 may provide a thermal energy conductive path vertically aligned with the device 122 between the die 102 and the package substrate 104. Without such overlap, air, underfill, or some other material that may not conduct thermal energy as well may be vertically aligned with the device 122 between the die 102 and the package substrate 104, which may provide for poor thermal conductance. Additionally, in the illustrated example of FIG. 1, between at least some of the lateral portion 156 of the die-package interconnect 110 and the first insulation layer 130, there is no second insulation layer 136 (e.g., at axis 150). In some examples, the second insulation layer 136 is not completely removed from between the lateral portion 156 and the first insulation layer 130 but has a reduced thickness compared with the second insulation layer 136 on the lateral periphery of the die-package interconnect 110 and away from the lateral portion 156. As described above, the second insulation layer 136 has a lower thermal conductivity than the first insulation layer 130. By removing (or reducing) the second insulation layer 136 between the first insulation layer 130 and by adding the lateral portion 156 of the die-package interconnect 110, the thermal conduction away from device 122 via metal layer 126b and the lateral portion 156 of the die-package interconnect 110 to the package substrate 104, along the path 160, can be facilitated.

The semiconductor device assembly 100 includes a molding compound 170 laterally around and encapsulating the die 102. Although not illustrated, the semiconductor device assembly 100 may include other components. For example, the semiconductor device assembly 100 may include underfill between the die 102 and the package substrate 104 and laterally around the die-package interconnect 110. Other components may be included.

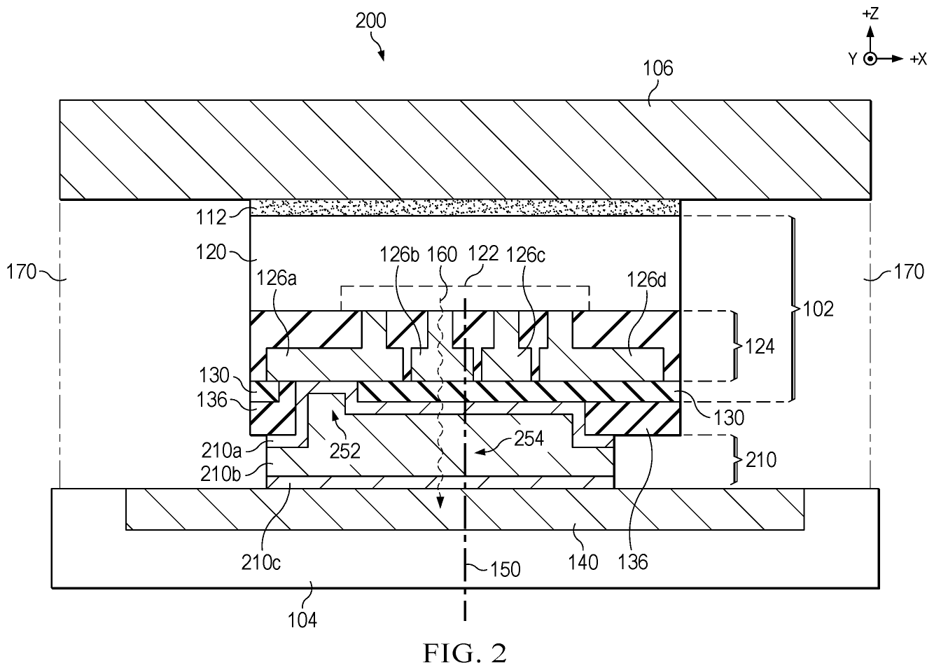

FIG. 2 illustrates a cross-sectional view of a semiconductor device assembly 200 according to some examples. The semiconductor device assembly 200 includes at least some components of the semiconductor device assembly 100 of FIG. 1 and a die-package interconnect 210. The die-package interconnect 210 includes an UBM 210a, a pillar or bump 210b (referred to as “bump 210b” for ease), and solder 210c. The UBM 210a is conformal along an outer surface of the second insulation layer 136, along sidewall surfaces of the opening through the second insulation layer 136, along a surface of the metal layer 126a exposed through an opening through the first insulation layer 130 and the opening of the second insulation layer 136, and along sidewall surfaces and on a surface of the first insulation layer 130 exposed through the opening through the second insulation layer 136. The UBM 210a may be or include one or more layers of copper (Cu), nickel (Ni), aluminum (Al), titanium (Ti), an alloy thereof, or the like. The bump 210b is on the UBM 210a. The bump 210b may be or include copper, a copper alloy, or the like. The solder 210c is on the bump 210b and attaches and electrically couples to the metal layer 140 of the package substrate 104. Other types of die-package interconnects may be implemented in other examples.

The die-package interconnect 210 overlaps (e.g., vertically overlaps) the device 122 (e.g., transistor) in the active area on the semiconductor substrate 120. At least a portion of the die-package interconnect 210 intersects with a direction normal to the front side surface (e.g., a z-direction) of the semiconductor substrate 120 at the device 122 (e.g., at axis 150). The die-package interconnect 210 includes a vertical/column portion 252 and a lateral portion 254. The vertical portion 252 overlaps, contacts, and is electrically coupled to the metal layer 126a through the opening through the second insulation layer 136 and the opening through the first insulation layer 130. The lateral portion 254 extends laterally from the vertical portion 252 and is on and contacts the first insulation layer 130 laterally from the opening through the first insulation layer 130 that exposes the metal layer 126a. The lateral portion 254 overlaps with the device 122 (e.g., transistor). The lateral portion 254 intersects the axis 150. As shown, no second insulation layer 136 is between at least some of the lateral portion 254 and the first insulation layer 130. The second insulation layer 136 abuts a lateral periphery (e.g., in both x and y-directions, in some examples) of the die-package interconnect 210. The illustrated die-package interconnect 210 may be referred to as a cantilever die-package interconnect. The die-package interconnect 210 is attached to a metal layer (e.g., metal layer 126a) at one end and extends laterally from that metal layer without attaching to another metal layer of the die 102 (e.g., of the metallization structure 124). The cantilever die-package interconnect can have an elongated footprint (e.g., on the x-y plane), such as a rectangular footprint, an oval footprint, an oblong footprint, etc.

Like the semiconductor device assembly 100 of FIG. 1, the semiconductor device assembly 200 may provide for a more direct thermal conduction path 160 from the device 122 to the package substrate 104. The die-package interconnect 210 may provide a thermal energy conductive path vertically aligned with the device 122 between the die 102 and the package substrate 104. Additionally, in the illustrated example of FIG. 2, between at least some of the lateral portion 254 of the die-package interconnect 210 and the first insulation layer 130, there is no second insulation layer 136 (e.g., at axis 150). By not having the second insulation layer 136 in such a location, a barrier to improved thermal energy conductance may be removed, which may permit improved thermal conduction along the path 160.

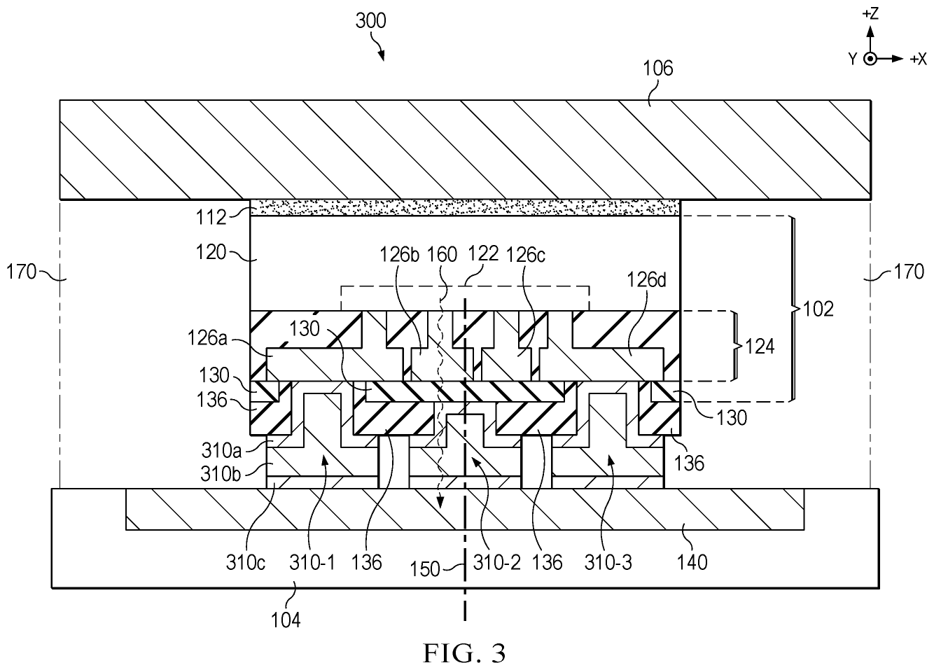

FIG. 3 illustrates a cross-sectional view of a semiconductor device assembly 300 according to some examples. The semiconductor device assembly 300 includes at least some components of the semiconductor device assembly 100 of FIG. 1 and die-package interconnects 310-1, 310-2, 310-3. Each die-package interconnect 310-1, 310-2, 310-3 includes an UBM 310a, a pillar or bump 310b (referred to as “bump 310b” for ease), and solder 310c. In the die-package interconnect 310-1, the UBM 310a is conformal along an outer surface of the second insulation layer 136, along sidewall surfaces of an opening through the second insulation layer 136, and along a surface of the metal layer 126a exposed through respective openings through the first insulation layer 130 and the second insulation layer 136. In the die-package interconnect 310-2, the UBM 310a is conformal along the outer surface of the second insulation layer 136, along sidewall surfaces of an opening through the second insulation layer 136, and along a surface of the first insulation layer 130. In the die-package interconnect 310-3, the UBM 310a is conformal along the outer surface of the second insulation layer 136, along sidewall surfaces of an opening through the second insulation layer 136, and along a surface of the metal layer 126d exposed through respective openings through the first insulation layer 130 and the second insulation layer 136. In each die-package interconnect 310-1, 310-2, 310-3, the respective bump 310b is on the respective UBM 310a, and the respective solder 310c is on the respective bump 310b. The UBM 310a may be or include one or more layers of copper (Cu), nickel (Ni), aluminum (Al), titanium (Ti), an alloy thereof, or the like. The bump 310b may be or include copper, a copper alloy, or the like. The solder 310c of the die-package interconnects 310-1, 310-2, 310-3 attach and electrically couple to the metal layer 140 of the package substrate 104. Other types of die-package interconnects may be implemented in other examples.

The die-package interconnect 310-2 overlaps (e.g., vertically overlaps) the device 122 (e.g., transistor) in the active area on the semiconductor substrate 120. At least a portion of the die-package interconnect 310-2 intersects with a direction normal to the front side surface (e.g., a z-direction) of the semiconductor substrate 120 at the device 122 (e.g., at axis 150). The die-package interconnect 310-2 contacts the first insulation layer 130. The die-package interconnect 310-2 may be electrically isolated from metal layers 126b and 126c. As shown, no second insulation layer 136 is between at least some of the die-package interconnect 310-2 and the first insulation layer 130. The second insulation layer 136 abuts a lateral periphery (e.g., in both x and y-directions, in some examples) of the die-package interconnect 310-2. The illustrated die-package interconnect 310-2 may be referred to as a dummy die-package interconnect, a dummy thermal die-package interconnect, a thermal die-package interconnect, or the like. The die-package interconnect 310-2 is not attached to or electrically coupled to a metal layer in the uppermost metallization layer of the metallization structure 124.

Like the semiconductor device assembly 100 of FIG. 1, the semiconductor device assembly 300 may provide for a more direct thermal conduction path 160 from the device 122 to the package substrate 104. The die-package interconnect 310-2 may provide a thermal energy conductive path vertically aligned with the device 122 between the die 102 and the package substrate 104. Additionally, in the illustrated example of FIG. 3, between at least some of the die-package interconnect 310-2 and the first insulation layer 130, there is no second insulation layer 136 (e.g., at axis 150). By not having the second insulation layer 136 in such a location, a barrier to improved thermal energy conductance may be removed, which may permit improved thermal conduction along the path 160.

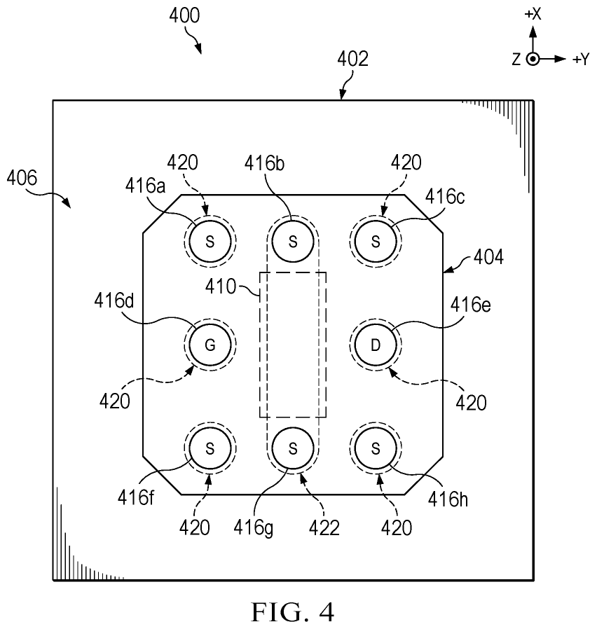

FIG. 4 is a layout view of a die 400 according to some examples. The die 400 has a die layout 402, which may be a front side of the die 400. In the die layout 402, the die 400 includes a circuit area 404 and a scribe area 406 circumscribing the circuit area 404. Metallization layers in a metallization structure may be routed within, and devices may be formed on a semiconductor substrate in, the circuit area 404. The scribe area 406 may be or include otherwise un-used areas of the die 400 that provide a processing tolerance for sawing or scribing the die 400 during singulation.

An active area 410 is in the circuit area 404. The active area 410 is the area in which a device (e.g., device 122) is formed on the semiconductor substrate of the die 400. The active area 410 may be defined on the semiconductor substrate by isolation regions (such as shallow trench isolation (STI) regions in or on the semiconductor substrate). In examples in which the device is a transistor, the transistor may have a single finger layout or a multi-finger layout in the active area 410. In a single finger layout, the transistor includes one source region and one drain region in the active area of the semiconductor substrate and one gate structure on the active are of the semiconductor substrate. In a multi-finger layout, the transistor includes multiple source regions and multiple drain regions in the active area and multiple gate structures on the active area, where the source regions are electrically coupled together (e.g., through the metallization structure), the drain regions are electrically coupled together, and the gate structures are electrically coupled together.

Metal layers 416a, 416b, 416c, 416d, 416c, 416f, 416g, 416h (e.g., in an uppermost metallization layer of a metallization structure) are exposed in the circuit area 404 (e.g., through first and second insulation layers). Assuming that the device in the active area 410 is a transistor, metal layers carrying a source voltage applied to a source region of the transistor are indicated by a “S”; metal layers carrying a drain voltage applied to a drain region of the transistor are indicated by a “D”; and metal layers carrying a gate voltage applied to a gate structure of the transistor are indicated by a “G”.

Die-package interconnects 420 are on the exposed metal layers 416a, 416c, 416d, 416e, 416f, 416h, respectively. A bridge die-package interconnect 422 is on the exposed metal layers 416b, 416g and extends laterally between the metal layers 416b, 416g to overlap the active area 410 (and hence, the device in the active area 410). A lateral portion of the bridge die-package interconnect 422 (e.g., like lateral portion 156 in FIG. 1) overlaps the active area 410 (and hence, the device in the active area 410). The bridge die-package interconnect 422 connects to metal layers 416b, 416g that carry a same signal and/or voltage. Assuming that the device in the active area 410 is a transistor, the metal layers 416b, 416g conduct a current to/from a source region of the transistor (e.g., via metallization layers in the metallization structure coupled to the source region) and may carry a source voltage. The metal layer 416d carries a gate voltage applied to a gate of the transistor. Also, the metal layer 416e conducts a current to/from a drain region of the transistor (e.g., via the metallization structure) and may carry a drain voltage. In the illustrated example, the bridge die-package interconnect 422 may extend laterally between the metal layers 416b, 416g (e.g., the lateral portion of the bridge die-package interconnect 422) in a direction parallel or perpendicular to a channel length direction of a channel region of a transistor in the active area 410, and metal layers 416b and 416g can overlap, respectively, vertical portions of the bridge die-package interconnect 422. Metal layers 416a, 416b, and 416c may also be electrically connected to a first metal layer (not shown in FIG. 4), and metal layers 416f, 416g, and 416h may also be electrically connected to a second metal layer (not shown in FIG. 4), with both first and second metal layers electrically connected to bridge die-package interconnect 422.

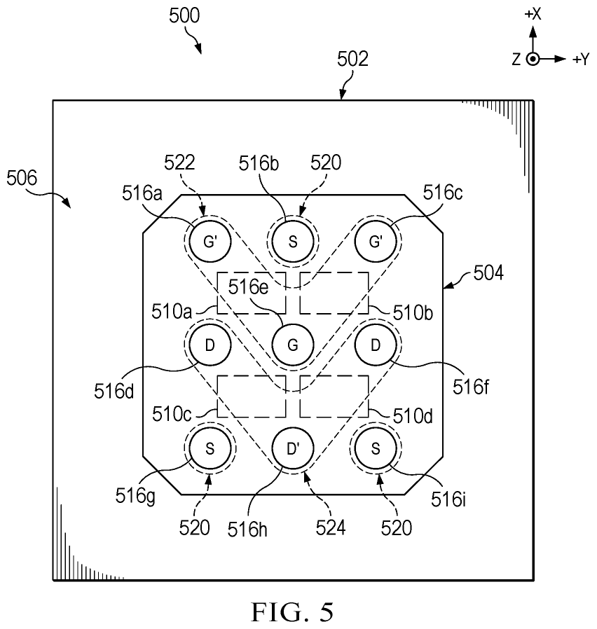

FIG. 5 is a layout view of a die 500 according to some examples. The die 500 has a die layout 502, which may be a front side of the die 500. In the die layout 502, the die 500 includes a circuit area 504 and a scribe area 506 circumscribing the circuit area 504. Circuit area 504 may include one or more transistors.

Separated, distinct active areas 510a, 510b, 510c, 510d are in the circuit area 504. Each active area 510a, 510b, 510c, 510d is the area in which a device (e.g., device 122), or portion thereof, is formed on the semiconductor substrate of the die 500. Each active area 510a, 510b, 510c, 510d may be defined on the semiconductor substrate by isolation regions. In examples in which the device is a transistor, the transistor may include respective portions in the active areas 510a, 510b, 510c, 510d, and each portion of the transistor may have a single finger layout or a multi-finger layout in the respective active area 510a, 510b, 510c, 510d. The multiple source regions in the active areas 510a-510d are electrically coupled together (e.g., in the metallization structure); the multiple drain regions in the active areas 510a-510d are electrically coupled together; and the multiple gate structures on the active areas 510a-510d are electrically coupled together. The transistor, in such a circumstance, may be referred to as a quad (e.g., for the four active areas in which the transistor is formed). Distributing portions of the transistor in such a manner may spread or distribute thermal energy generation more in the die 500, which may result in more efficient thermal conduction.

Metal layers 516a, 516b, 516c, 516d, 516c, 516f, 516g, 516h, 516i (e.g., in an uppermost metallization layer of a metallization structure) are exposed in the circuit area 504 (e.g., through first and second insulation layers). Assuming that the device in the active areas 510a-510d is a transistor, the metal layers carrying a source voltage applied to a source region of the transistor are indicated by a “S”; metal layers carrying a drain voltage applied to a drain region of the transistor are indicated by a “D”; and metal layers carrying a gate voltage applied to a gate structure of the transistor are indicated by a “G”. Dummy metal layers are shown with an apostrophe appended to the “S”, “D”, or “G”. A dummy metal layer can provide a mechanical/electrical connection to a vertical portion of a die-package interconnect, but the dummy metal layers are not electrically connected to the region or structure indicated by the “S”, “D”, or “G” directly via the metallization structure. For example, a dummy metal G′ is not electrically connected to a gate of a transistor directly via the metallization structure; a dummy metal S′ is not electrically connected to a source region of the transistor directly via the metallization structure; and a dummy metal D′ is not electrically connected to a drain region directly via the metallization structure. In some examples, a dummy metal layer is not electrically coupled to another metal layer in the metallization structure of the die 500. In some examples, a dummy metal layer may be coupled to a metal layer(s) of underlying metallization layers of the metallization structure without further being electrically coupled to the indicated region or structure. A dummy metal layer attached to a bridge die-package interconnect may carry the voltage or signal that is on that bridge die-package interconnect.

Die-package interconnects 520 are on the exposed metal layers 516b, 516g, 516i, respectively. A bridge die-package interconnect 522 is on the exposed metal layers 516a, 516c. 516c and extends laterally between the metal layers 516a, 516e, 516c to overlap the active areas 510a, 510b (and hence, the portions of the device in the active areas 510a, 510b). A lateral portion of the bridge die-package interconnect 522 (e.g., like lateral portion 156 in FIG. 1) extending between the metal layers 516a, 516e overlaps the active area 510a (and hence, the portion of the device in the active area 510a). Another lateral portion of the bridge die-package interconnect 522 (e.g., like lateral portion 156 in FIG. 1) extending between the metal layers 516e, 516c overlaps the active area 510b (and hence, the portion of the device in the active area 510b). The bridge die-package interconnect 522 connects to a metal layer 516e that carries a signal and/or voltage and to dummy metal layers 516a, 516c that are permitted to carry the same signal and/or voltage as the metal layer 516e. In the illustrated example, the bridge die-package interconnect 522 may extend laterally between the metal layers 516a, 516e (e.g., a lateral portion of the bridge die-package interconnect 522) in a direction that is diagonal to a channel length direction of a channel region of a transistor in the active area 510a, and may extend laterally between the metal layers 516c. 516c (e.g., a lateral portion of the bridge die-package interconnect 522) in a direction that is diagonal to a channel length direction of a channel region of a transistor in the active area 510b.

A bridge die-package interconnect 524 is on the exposed metal layers 516d, 516h, 516f and extends laterally between the metal layers 516d, 516h, 516f to overlap the active areas 510c. 510d (and hence, the portions of the device in the active areas 510c, 510d). A lateral portion of the bridge die-package interconnect 524 (e.g., like lateral portion 156 in FIG. 1) extending between the metal layers 516d, 516h overlaps the active area 510c (and hence, the portion of the device in the active area 510c). Another lateral portion of the bridge die-package interconnect 524 (e.g., like lateral portion 156 in FIG. 1) extending between the metal layers 516h, 516f overlaps the active area 510d (and hence, the portion of the device in the active area 510d). The bridge die-package interconnect 524 connects to metal layers 516d, 516f that carry a same signal and/or voltage and to a dummy metal layer 516h that is permitted to carry the same signal and/or voltage as the metal layers 516d, 516f. In the illustrated example, the bridge die-package interconnect 524 may extend laterally between the metal layers 516d, 516h (e.g., a lateral portion of the bridge die-package interconnect 524) in a direction that is diagonal to a channel length direction of a channel region of a transistor in the active area 510c, and may extend laterally between the metal layers 516h, 516f (e.g., a lateral portion of the bridge die-package interconnect 524) in a direction that is diagonal to a channel length direction of a channel region of a transistor in the active area 510d.

Routing metal layers in metallization layers of the metallization structure may permit forming the illustrated arrangement (or another arrangement) of exposed metal layers carrying appropriate signals or voltages, which may enable the bridge die-package interconnects being formed overlapping active areas. By arranging metal layers and inserting dummy metal layers to which bridge die-package interconnects could be attached, lateral portions of the bridge die-package interconnects may be arranged to extend laterally diagonally overlapping active areas to provide a thermal conduction path. This may permit forming active areas in various arrangements while providing thermal conduction paths.

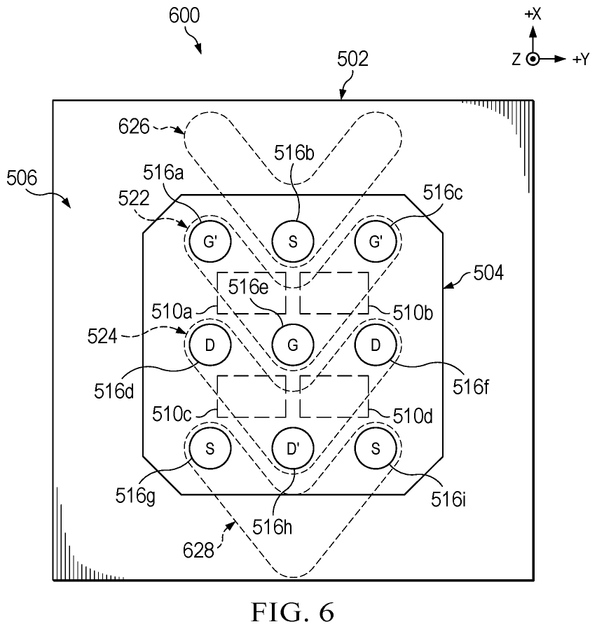

FIG. 6 is a layout view of a die 600 according to some examples. The die 600 has at least some of the components of the die 500 of FIG. 5 and includes a cantilever die-package interconnect 626 and a bridge/cantilever die-package interconnect 628. The cantilever die-package interconnect 626 is on the exposed metal layer 516b and extends laterally onto the scribe area 506. A first lateral portion of the cantilever die-package interconnect 626 extends from the metal layer 516b in a direction having a negative y-direction component and a positive x-direction component onto the scribe area 506. A second lateral portion of the cantilever die-package interconnect 626 extends from the metal layer 516b in a direction having a positive y-direction component and a positive x-direction component onto the scribe area 506. The bridge/cantilever die-package interconnect 628 is on the exposed metal layers 516g, 516i and extends laterally onto the scribe area 506. The bridge/cantilever die-package interconnect 628 may be considered cantilevered considering x-direction components (e.g., the bridge/cantilever die-package interconnect 628 is cantilevered in an x-direction). A first lateral portion of the bridge/cantilever die-package interconnect 628 extends from the metal layer 516g onto the scribe area 506, and a second lateral portion of the bridge/cantilever die-package interconnect 628 extends from the first lateral portion on the scribe area to the metal layer 516i. The bridge/cantilever die-package interconnect 628 connects to metal layers 516g, 516i that carry a same signal and/or voltage. Implementing the cantilever die-package interconnect 626 and bridge/cantilever die-package interconnect 628 in FIG. 6 may result in more uniform stress on the die-package interconnects attached to the die 600 since the die-package interconnects under the die 600 are uniform.

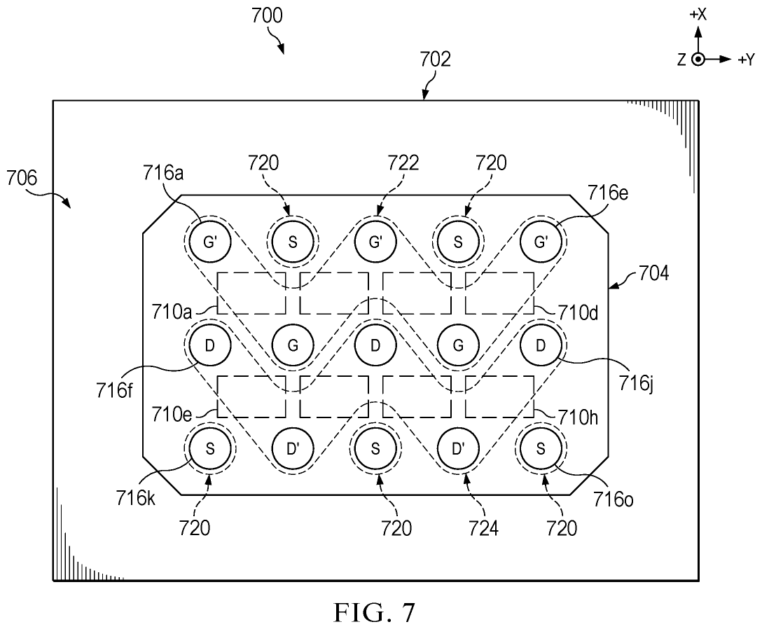

FIG. 7 is a layout view of a die 700 according to some examples. The die 700 illustrates further expansion of aspects illustrated in the die 500 of FIG. 5. Such aspects are apparent from FIGS. 5 and 7, and hence, description of various components of FIG. 7 is abbreviated. Additionally, some components are not explicitly labeled with reference numerals, although such reference numerals are apparent based on patterns of reference numerals in preceding figures.

The die 700 has a die layout 702, which may be a front side of the die 700. In the die layout 702, the die 700 includes a circuit area 704 and a scribe area 706 circumscribing the circuit area 704.

Separated, distinct active areas 710a through 710h are in the circuit area 704. Each active area 710a-710h is the area in which a device (e.g., device 122), or portion thereof, is formed on the semiconductor substrate of the die 700. Assuming the device is a transistor, the transistor may be referred to as an octal (e.g., for the eight active areas in which the transistor is formed). Distributing portions of the transistor in such a manner may spread or distribute thermal energy generation more in the die 700. Metal layers 716a through 716o (e.g., in an uppermost metallization layer of a metallization structure) are exposed in the circuit area 704 (e.g., through first and second insulation layers).

Die-package interconnects 720 are on the exposed metal layers 716b, 716d, 716k, 716m, 716o, respectively. A bridge die-package interconnect 722 is on the exposed metal layers 716a, 716g, 716c, 716i, 716e, and extends laterally between the metal layers 716a, 716g, 716c, 716i, 716e to overlap the active areas 710a-710d. A bridge die-package interconnect 724 is on the exposed metal layers 716f, 716, 716h, 716n, 716j, and extends laterally between the metal layers 716f, 716l, 716h, 716n, 716j to overlap the active areas 710e-710h. The bridge die-package interconnects 722, 724 may be referred to as lateral zig-zag bridge die-package interconnects.

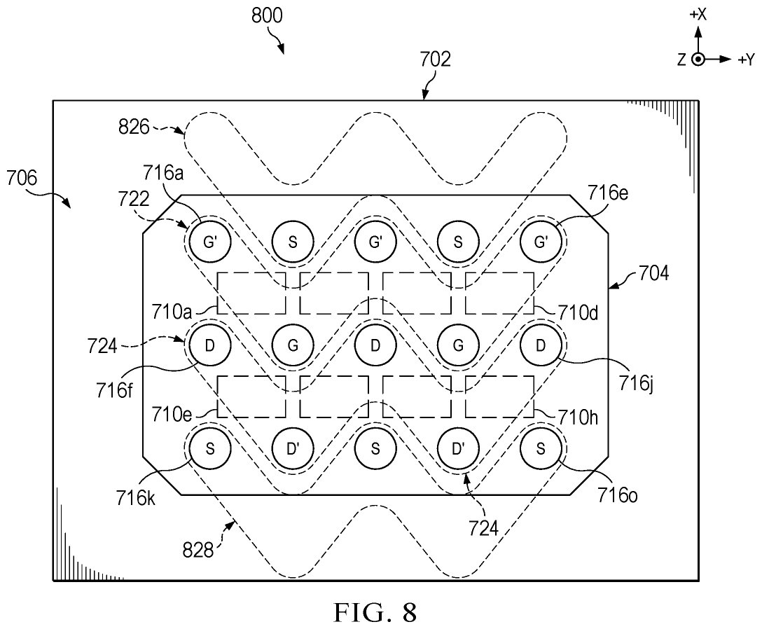

FIG. 8 is a layout view of a die 800 according to some examples. The die 800 has at least some of the components of the die 700 of FIG. 7 and includes bridge/cantilever die-package interconnects 826, 828. The die 800 illustrates further expansion of aspects illustrated in the die 600 of FIG. 6. Such aspects are apparent from FIGS. 6 and 8, and hence, description of various components of FIG. 8 is abbreviated. The bridge/cantilever die-package interconnect 826 is on the exposed metal layers 716b, 716d and extends laterally onto the scribe area 506. The bridge/cantilever die-package interconnect 828 is on the exposed metal layers 716k, 716m, 716o and extends laterally onto the scribe area 506. The bridge/cantilever die-package interconnects 826, 828 may be referred to as lateral zig-zag bridge/cantilever die-package interconnects.

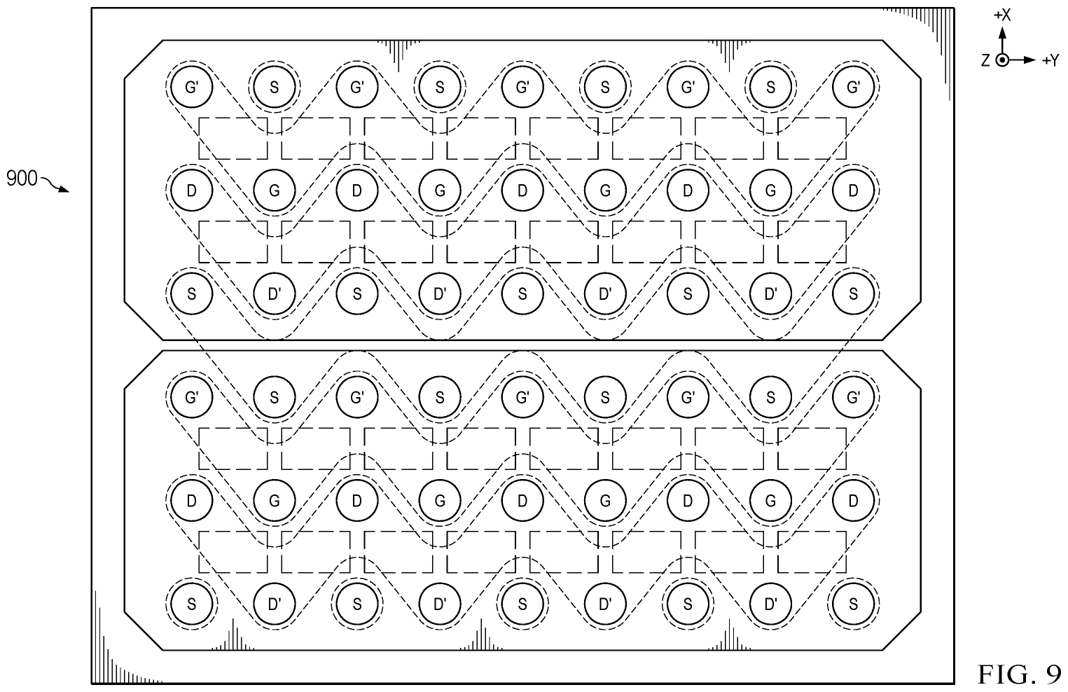

FIG. 9 is a layout view of a die 900 according to some examples. The die 900 is a further expansion of aspects of the dies 500, 700 of FIGS. 5 and 7, which is apparent from FIG. 9. Additionally, the aspects of the dies 600, 800 of FIGS. 6 and 8 may be applied to the die 900.

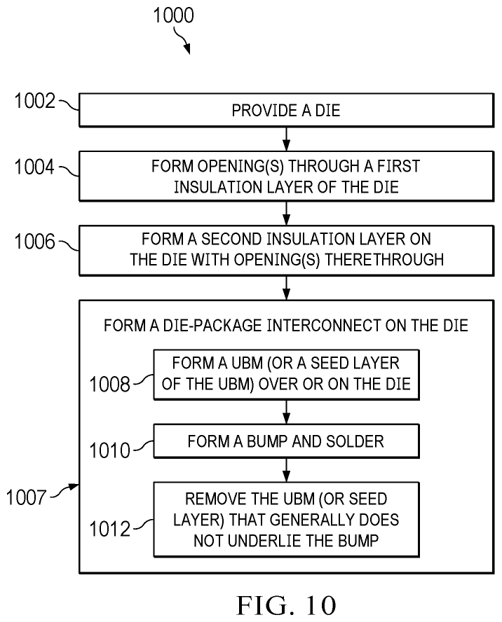

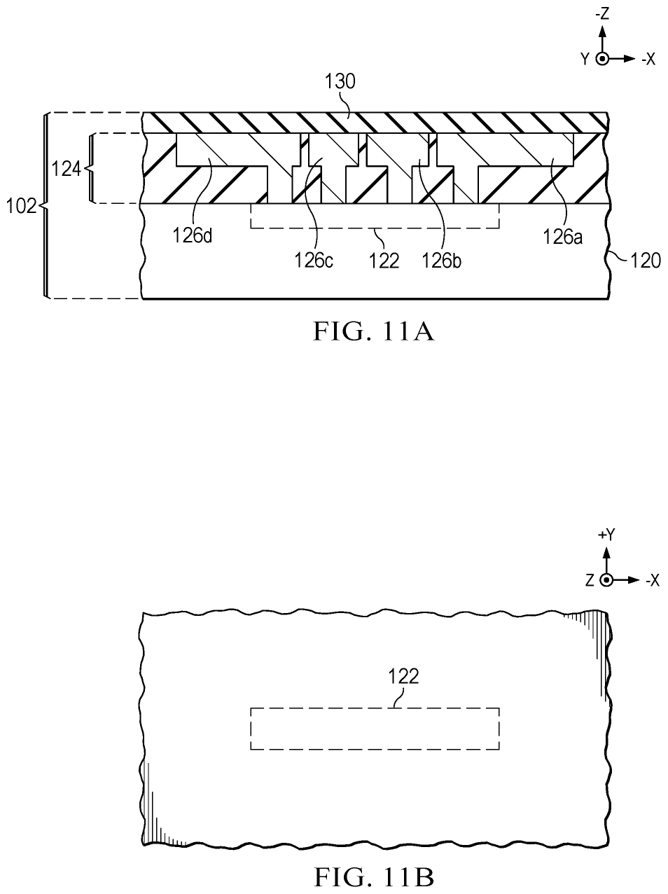

FIG. 10 is a flow chart of a method 1000 of manufacturing the semiconductor device assemblies 100, 200, 300 of FIGS. 1, 2, and 3 according to some examples. FIGS. 11A, 11B, 12A, 12B, 13A, 13B, 14, 15A, 15B, and 16 illustrate a method of manufacturing the semiconductor device assembly 100 of FIG. 1 according to some examples, which are described in the context of the method 1000 of FIG. 10. FIGS. 11A, 12A, 13A, 14, 15A, and 16 illustrate respective cross-sectional views of the die 102, and FIGS. 11B, 12B, 13B, and 15B illustrate alignment of openings corresponding to reticle masks for photolithography processes.

Referring to block 1002 of FIG. 10 and to FIG. 11A, the die 102 is provided. The die 102 has undergone front-end-of-the-line (FEOL) and back-end-of-the-line (BEOL) processing. The first insulation layer 130 has been formed without openings therethrough, and the metal layers 126a, 126b, 126c, 126d are not exposed through the first insulation layer 130. The layout view of FIG. 11B shows the relative placement of the device 122 (e.g., the active area in which the device 122 is formed). In some examples, die 102 can be singulated, and the subsequent operations can be performed as part of a packaging operation. In some examples, die 102 can be part of a wafer, and the subsequent operations can be performed as part of wafer-level processing operations, where the die-package interconnects are first formed on the wafer, and then the wafer is singulated.

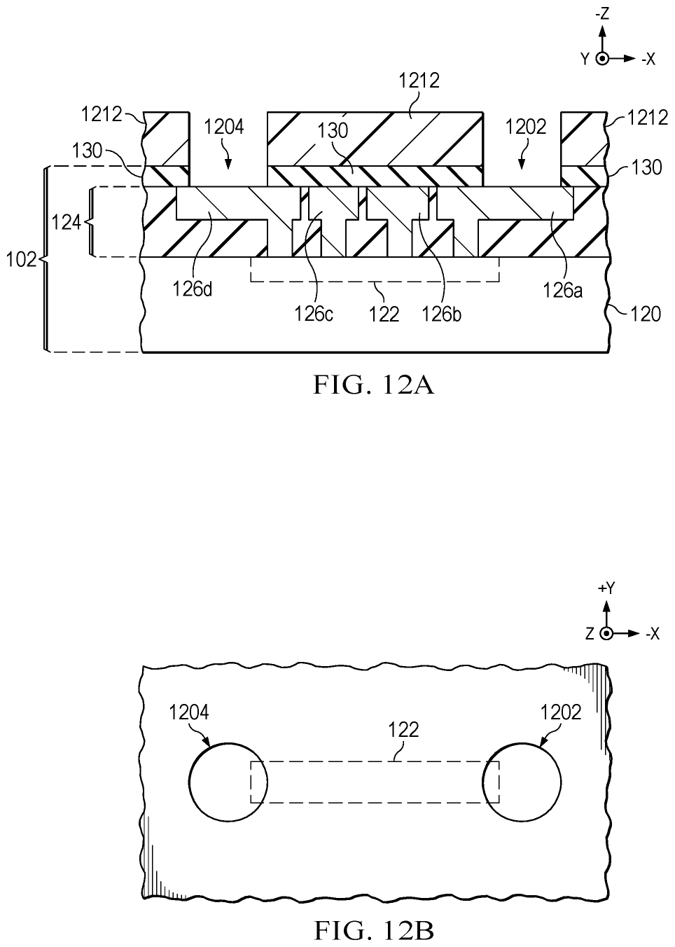

Referring to block 1004 of FIG. 10 and to FIG. 12A, openings 1202, 1204 are formed through the first insulation layer 130. The opening 1202 exposes the metal layer 126a through the first insulation layer 130, and the opening 1204 exposes the metal layer 126d through the first insulation layer 130. The openings 1202, 1204, as illustrated, are formed using a photolithography process. For example, to form the openings 1202, 1204, a photoresist 1212 is deposited (e.g., by spin-on) over and/or on the die 102 (e.g., over and/or on the first insulation layer 130) and patterned using photolithography. The photoresist 1212 is patterned to expose areas of the first insulation layer 130 where the openings 1202, 1204 are to be formed. With the patterned photoresist 1212 being used as a mask, an etch process, such as an anisotropic etch like a reactive ion etch (RIE) or the like, is performed to form the openings 1202, 1204 through the first insulation layer 130. The layout view of FIG. 12B illustrates the openings 1202, 1204, which corresponds with a reticle mask for patterning the photoresist 1212. After the etch process, the photoresist 1212 is removed, such as by ashing.

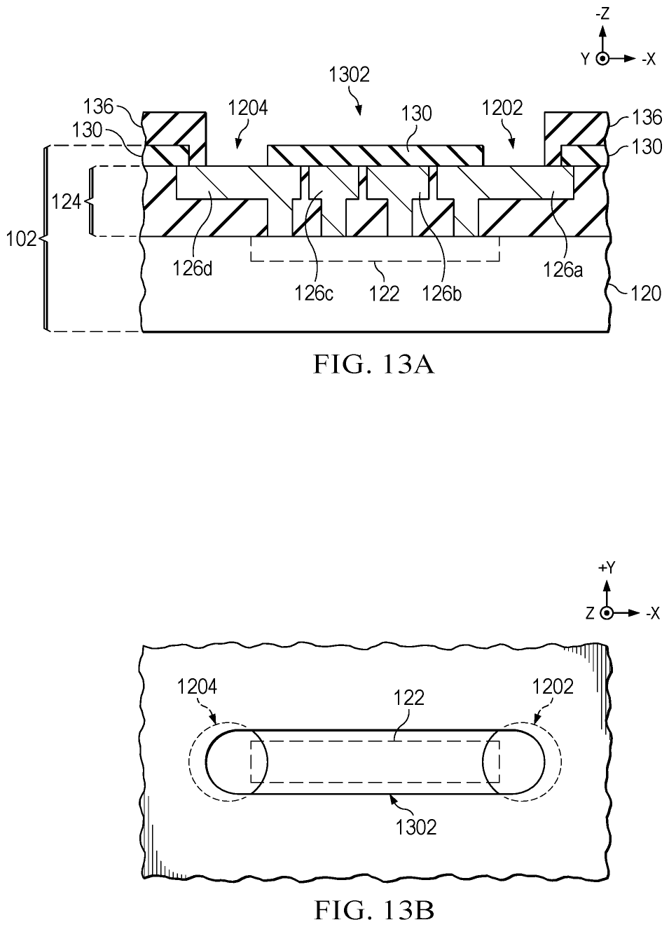

Referring to block 1006 of FIG. 10 and to FIG. 13A, the second insulation layer 136 is formed on the die 102 with an opening 1302 therethrough. The opening 1302 through the second insulation layer 136 exposes at least respective portions of the metal layers 126a, 126d exposed through the openings 1202, 1204 through the first insulation layer 130. Further, the opening 1302 exposes at least a portion of the first insulation layer 130 that overlaps the device 122. In some examples, the second insulation layer 136 is a photo-sensitive material, such as polyimide (PI), polybenzoxazole (PBO), benzocyclobutene (BCB), or the like. In such examples, the second insulation layer 136 may be deposited (e.g., by spin-on, vapor deposition, lamination, etc.) and patterned using photolithography. The patterning by photolithography results in a cured second insulation layer 136 having the opening 1302. The layout view of FIG. 12B illustrates the opening 1302, which corresponds with a reticle mask for patterning the second insulation layer 136, relative to the openings 1202, 1204 and the device 122. As shown in FIG. 12B, the opening 1302 overlaps at least a portion of the device 122.

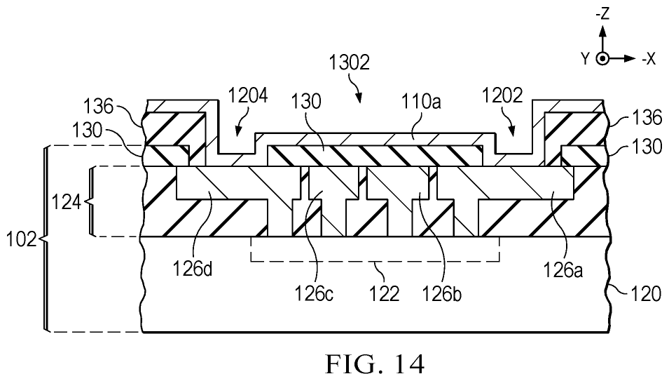

Referring to block 1007 of FIG. 10, the die-package interconnect 110 is formed on the die 102. Block 1007 includes blocks 1008, 1010, 1012. Referring to block 1008 of FIG. 10 and to FIG. 14, the UBM 110a (or a seed layer of the UBM 110a) is formed over or on the die 102. The UBM 110a (or seed layer) is formed along exposed surfaces, including the outer surface of the second insulation layer 136, sidewall surface of the second insulation layer 136 defining the opening 1302, an outer surface and sidewall surfaces of the first insulation layer 130 exposed through the opening 1302, an outer surface of the metal layer 126a exposed through the openings 1202, 1302, and an outer surface of the metal layer 126d exposed through the openings 1204, 1302. The UBM 110a (or seed layer) may be formed by any appropriate deposition process, such as physical vapor deposition (PVD), electroplating, or the like.

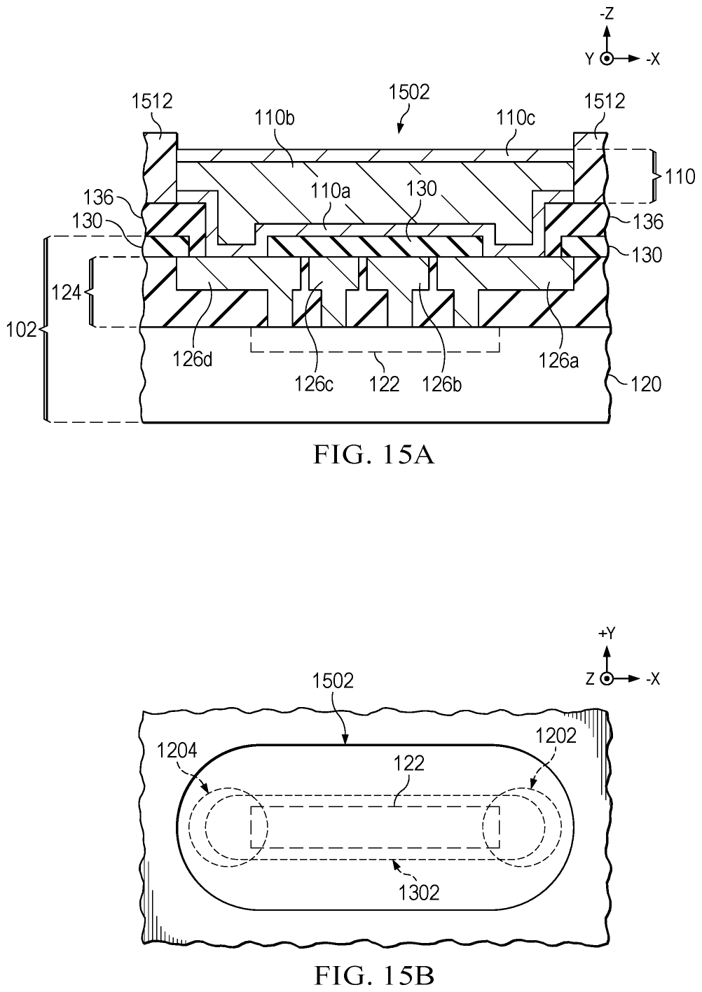

Referring to block 1010 of FIG. 10 and to FIG. 15A, the bump 110b and solder 110c are formed. In some examples, the bump 110b is formed using photolithography. For example, a photoresist 1512 is deposited (e.g., by spin-on) over and/or on the die 102 (e.g., over and/or on the UBM 110a (or seed layer)) and patterned using photolithography. The photoresist 1512 is patterned with an opening 1502 to expose an area of the UBM 110a (or seed layer) where the bump 110b is to be formed. With the patterned photoresist 1512, the bump 110b is deposited on the UBM 110a, such as by a plating process, which may be an electroplating process or electroless plating process, in the opening 1502. As indicated previously, a seed layer of the UBM 110a may be formed (e.g., with reference to FIG. 14), and with the photoresist 1512 patterned, a remainder of the UBM 110a may be deposited on the seed layer, such as by a plating process, in the opening 1502. The bump 110b may thereafter be formed on the UBM 110a in the opening 1502. Further, the solder 110c is deposited on the bump 110b, such as by a plating process, in the opening 1502. The solder 110c may be formed by other processes, such as a ball drop process, in other examples. The layout view of FIG. 15B illustrates the opening 1502, which corresponds with a reticle mask for patterning the photoresist 1512. As shown, the opening 1502 overlaps the openings 1202, 1204 through the first insulation layer 130 and the opening 1302 through the second insulation layer 136, which further overlaps the device 122. After the deposition (e.g., plating) process, the photoresist 1512 is removed, such as by ashing.

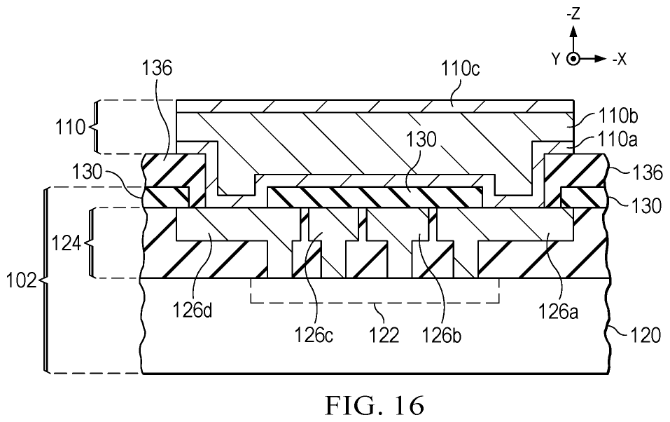

Referring to block 1012 of FIG. 10 and to FIG. 16, the UBM 110a (or seed layer) that underlied the photoresist 1512 and generally does not underlie the bump 110b is removed. The UBM 110a (or seed layer) may be removed by an etch process, which may be a wet etch. The bump 110b and/or solder 110c may mask etching the UBM 110a that underlies the bump 110b and is to remain as part of the die-package interconnect 110. An etch process may undercut the bump 110b some.

Referring to FIG. 1, back side processing of a wafer containing the die 102 (e.g., back grinding, forming the backside structure 112, etc.) may be performed, and then the die 102 can be singulated and attached to the package substrate 104. The die 102 may be placed on the package substrate 104 using a pick-and-place tool. The solder 110c is reflowed to attach or bond to the bump 110b and the metal layer 140 of the package substrate 104. The heat spreader 106 can be attached to the back side of the die 102. Other processing may be implemented, such as applying an underfill, applying a molding compound, etc.

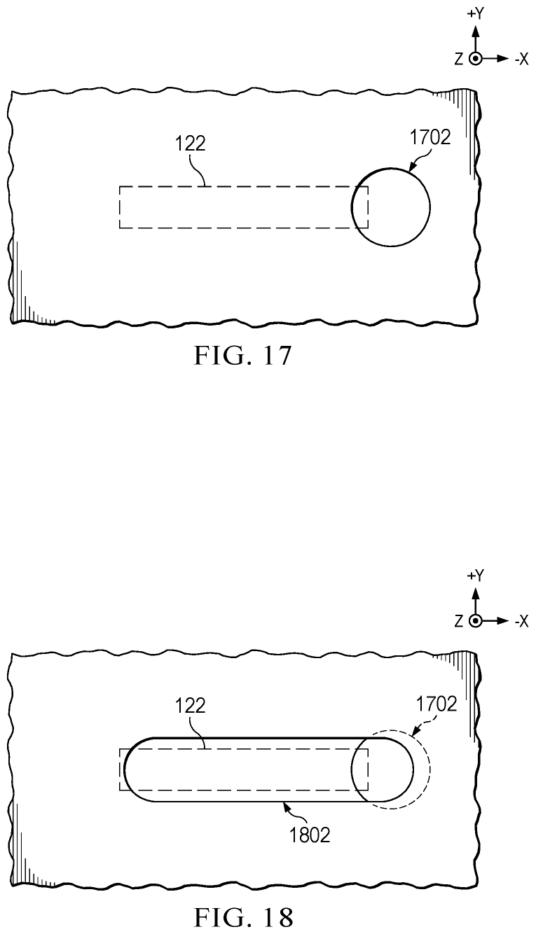

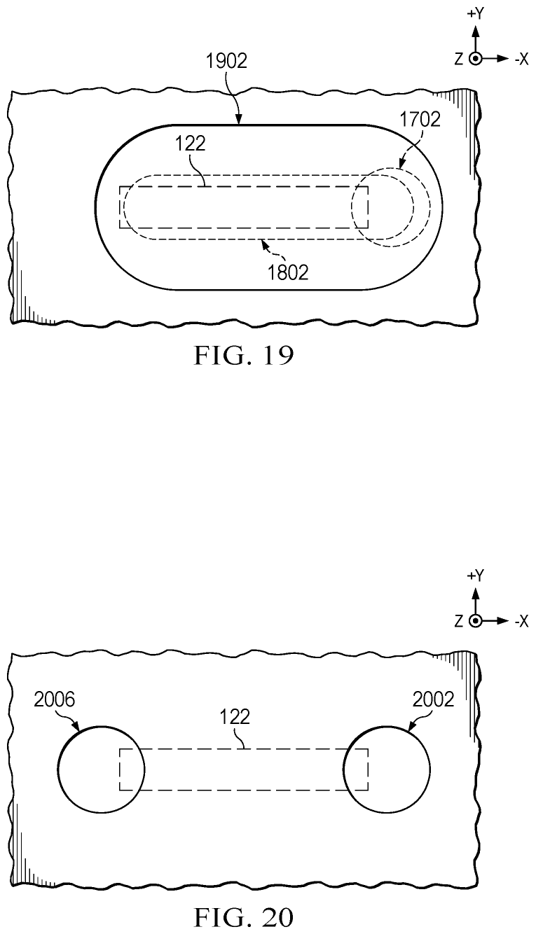

The semiconductor device assembly 200 of FIG. 2 may be manufactured like described above with respect to FIG. 10 and FIGS. 11A, 12A, 13A, 14, 15A, and 16. FIGS. 17, 18, and 19 illustrate alignment of openings corresponding to reticle masks for photolithography processes in manufacturing the cantilever die-package interconnect of the semiconductor device assembly 200. The alignment of an opening corresponding to a reticle mask shown in FIG. 17 may be for patterning the photoresist 1212 of FIG. 12A. The alignment of an opening corresponding to a reticle mask shown in FIG. 18 may be for patterning the second insulation layer 136 in FIG. 13A. The alignment of an opening corresponding to a reticle mask shown in FIG. 19 may be for patterning the photoresist 1512 of FIG. 15A.

With reference to block 1004 of FIG. 10, FIG. 17 shows an opening 1702 formed through the first insulation layer 130, which exposes the metal layer 126a. With reference to block 1006 of FIG. 10, FIG. 18 shows an opening 1802 formed through the second insulation layer 136, which exposes the metal layer 126a exposed through the opening 1702 through the first insulation layer 130 and exposes a surface of the first insulation layer 130 overlapping the device 122. With reference to block 1010 of FIG. 10, FIG. 19 shows an opening 1902 of a photoresist in which the bump 210b is formed. The opening 1902 exposes the surfaces exposed through the opening 1802, and hence the bump 210b (or more generally, the die-package interconnect 210) is formed at least in part in the openings 1702, 1802. Various other aspects are apparent in view of these figures, the method of manufacturing described with respect to FIGS. 11A, 12A, 13A, 14, 15A, and 16, and the description of the semiconductor device assembly 200 of FIG. 2.

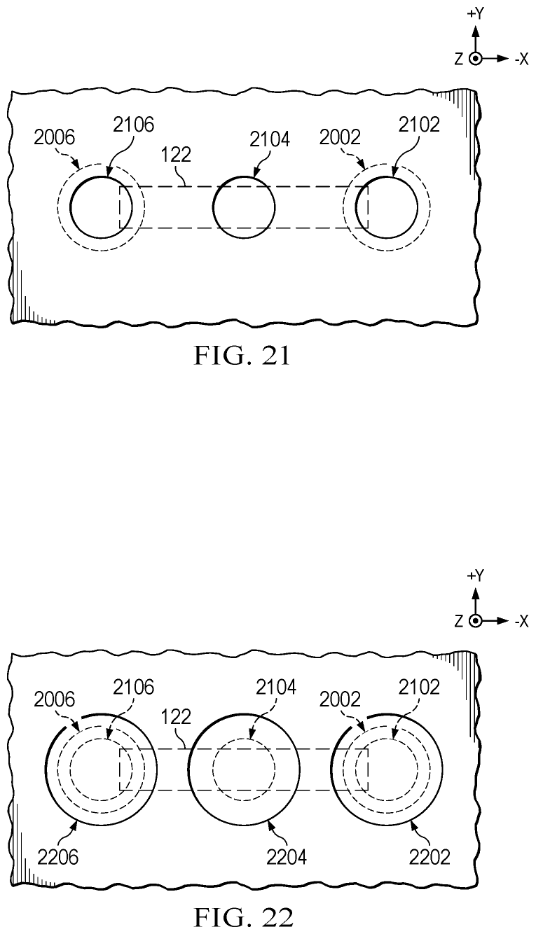

The semiconductor device assembly 300 of FIG. 3 may be manufactured like described above with respect to FIGS. 11A, 12A, 13A, 14, 15A, and 16. FIGS. 20, 21, and 22 illustrate alignment of openings corresponding to reticle masks for photolithography processes in manufacturing the semiconductor device assembly 300. The alignment of openings corresponding to a reticle mask shown in FIG. 20 may be for patterning the photoresist 1212 of FIG. 12A. The alignment of openings corresponding to a reticle mask shown in FIG. 21 may be for patterning the second insulation layer 136 in FIG. 13A. The alignment of openings corresponding to a reticle mask shown in FIG. 22 may be for patterning the photoresist 1512 of FIG. 15A.

With reference to block 1004 of FIG. 10, FIG. 20 shows openings 2002, 2006 formed through the first insulation layer 130, which expose the metal layers 126a, 126d, respectively. With reference to block 1006 of FIG. 10, FIG. 21 shows openings 2102, 2104, 2106 formed through the second insulation layer 136. The opening 2102 exposes the metal layer 126a exposed through the opening 2002 through the first insulation layer 130. The opening 2104 exposes a surface of the first insulation layer 130 overlapping the device 122. The opening 2106 exposes the metal layer 126d exposed through the opening 2006 through the first insulation layer 130. With reference to block 1010 of FIG. 10, FIG. 22 shows openings 2202, 2204, 2206 of a photoresist in which the respective bumps 310b of the die-package interconnects 310-1, 310-2, 310-3 are formed. The opening 2202 exposes the surfaces exposed through the opening 2102, and hence the bump 310b of the die-package interconnect 310-1 (or more generally, the die-package interconnect 310-1) is formed at least in part in the openings 2002, 2102. The opening 2204 exposes the surfaces exposed through the opening 2104, and hence the bump 310b of the die-package interconnect 310-2 (or more generally, the die-package interconnect 310-2) is formed at least in part in the opening 2104. The opening 2206 exposes the surfaces exposed through the opening 2106, and hence the bump 310b of the die-package interconnect 310-3 (or more generally, the die-package interconnect 310-3) is formed at least in part in the openings 2006, 2106. Various other aspects are apparent in view of these figures, the method of manufacturing described with respect to FIGS. 11A, 12A, 13A, 14, 15A, and 16, and the description of the semiconductor device assembly 300 of FIG. 3.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Also, in this description, the recitation “based on” means “based at least in part on.” Therefore, if X is based on Y, then X may be a function of Y and any number of other factors.

A device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

While the use of particular transistors is described herein, other transistors (or equivalent devices) may be used instead with little or no change to the remaining circuitry. For example, a field effect transistor (“FET”) (such as an n-channel FET (NFET) or a p-channel FET (PFET)), a bipolar junction transistor (BJT—e.g., NPN transistor or PNP transistor), an insulated gate bipolar transistor (IGBT), a junction field effect transistor (JFET), a high electron mobility transistor (HEMT), a metal insulator semiconductor FET (MISFET), a metal insulator semiconductor HEMT (MISHEMT), a metal oxide semiconductor HEMT (MOSHEMT), and/or the like may be used in place of or in conjunction with the devices described herein. The transistors may be depletion mode devices, drain-extended devices, enhancement mode devices, natural transistors or other types of device structure transistors. Furthermore, the devices may be implemented in/over a silicon substrate (Si), a silicon carbide substrate (SiC), a gallium nitride substrate (GaN) or a gallium arsenide substrate (GaAs).

References may be made in the claims to a transistor's control input and its current terminals. In the context of a FET, the control input is the gate, and the current terminals are the drain and source. In the context of a BJT, the control input is the base, and the current terminals are the collector and emitter.

References herein to a FET being “on” or “enabled” means that the conduction channel of the FET is present and drain current may flow through the FET. References herein to a FET being “off” or “disabled” means that the conduction channel is not present so drain current does not flow through the FET. An “off” FET, however, may have current flowing through the transistor's body-diode.

Circuits described herein are reconfigurable to include additional or different components to provide functionality at least partially similar to functionality available prior to the component replacement. Components shown as resistors, unless otherwise stated, are generally representative of any one or more elements coupled in series and/or parallel to provide an amount of impedance represented by the resistor shown. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor.

While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description.

In this description, unless otherwise stated, “about,” “approximately” or “substantially” preceding a parameter means being within +/−10 percent of that parameter or, if the parameter is zero, a reasonable range of values around zero.

Modifications are possible in the described embodiments, and other embodiments are possible, within the scope of the claims.

Although various examples have been described in detail, it should be understood that various changes, substitutions, and alterations can be made therein without departing from the scope defined by the appended claims.

What is claimed is:

1. A semiconductor device assembly comprising:
a semiconductor substrate including a transistor;
a metallization structure on the semiconductor substrate and including a first metal layer;
a package substrate having a second metal layer;
a die-package interconnect between the metallization structure and the second metal layer, the die-package interconnect overlapping at least part of the transistor; and
one or more insulation layers on the metallization structure, the one or more insulation layers having a first portion having a first thickness and a second portion having a second thickness, the first portion being outside a footprint of the transistor, the second portion being between the die-package interconnect and the at least part of the transistor, the first thickness being larger than the second thickness.

2. The semiconductor device assembly of claim 1, wherein the die-package interconnect includes a vertical portion and a lateral portion, the vertical portion overlapping and electrically coupled to the first metal layer, and the lateral portion overlapping the at least part of the transistor.

3. The semiconductor device assembly of claim 2, wherein the metallization structure includes a third metal layer, the first metal layer and the third metal layer being on opposite sides of the transistor, wherein:
the vertical portion is a first vertical portion;
the die-package interconnect includes a second vertical portion overlapping and electrically coupled to third metal layer; and
the lateral portion is between the first vertical portion and the second vertical portion.

4. The semiconductor device assembly of claim 3, wherein the lateral portion extends along an axis diagonal to a channel length of a channel region of the transistor.

5. The semiconductor device assembly of claim 1, wherein the die-package interconnect is electrically isolated from the first metal layer.

6. The semiconductor device assembly of claim 1, wherein each of the first and second portions of one or more insulation layers includes a first insulation layer, the first insulation layer including at least one of an oxide or a nitride.

7. The semiconductor device assembly of claim 6, wherein the first portion includes the first insulation layer and a second insulation layer, and the second portion includes the first insulation layer.

8. The semiconductor device assembly of claim 7, wherein the second insulation layer includes at least one of: polyimide, polybenzoxazole, or benzocyclobutene.

9. The semiconductor device assembly of claim 7, wherein each of the first and second portion includes the first insulation layer and the second insulation layer, the second insulation layer of the second portion being thinner than the second insulation layer of the first portion.

10. The semiconductor device assembly of claim 1, wherein:
the die-package interconnect includes an under bump metallization (UBM) and a metal bump forming a stack.

11. The semiconductor device assembly of claim 1, wherein:
the semiconductor substrate includes at least four active areas, each active area of the active areas including at least a portion of the transistor;
the die-package interconnect is a first die-package interconnect;
the first die-package interconnect includes a first lateral portion and a second lateral portion;
the first lateral portion overlaps a first active area of the active areas;
the second lateral portion overlaps a second active area of the active areas;
the semiconductor device assembly further includes a second die-package interconnect between the metallization structure and the package substrate;
the second die-package interconnect includes a third lateral portion and a fourth lateral portion;
the third lateral portion overlaps a third active area of the active areas; and
the fourth lateral portion overlaps a fourth active area of the active areas.

12. The semiconductor device assembly of claim 1, wherein:
the semiconductor substrate includes at least eight active areas, each active area of the active areas including at least a portion of the transistor;
the die-package interconnect is a first die-package interconnect;
the first die-package interconnect includes a first lateral portion, and a second lateral portion, a third lateral portion, and a fourth lateral portion;
the first lateral portion overlaps a first active area of the active areas;
the second lateral portion overlaps a second active area of the active areas;
the third lateral portion overlaps a third active area of the active areas;
the fourth lateral portion overlaps a fourth active area of the active areas;
the semiconductor device assembly further includes a second die-package interconnect between the metallization structure and the package substrate;
the second die-package interconnect includes a fifth lateral portion, a sixth lateral portion, a seventh lateral portion, and an eighth lateral portion;
the fifth lateral portion overlaps a fifth active area of the active areas;
the sixth lateral portion overlaps a sixth active area of the active areas;
the seventh lateral portion overlaps a seventh active area of the active areas; and
the eighth lateral portion overlaps an eighth active area of the active areas.

13. A method comprising:
providing a die comprising:
a semiconductor substrate including a transistor; and
a metallization structure on the semiconductor substrate and including a metal layer; and
forming a die-package interconnect on the die, the die-package interconnect being on a side of the metallization structure distal from the semiconductor substrate, the die-package interconnect overlapping at least part of the transistor.

14. The method of claim 13, further comprising attaching the die to a package substrate, the die-package interconnect being attached to the package substrate.

15. The method of claim 13, wherein:
the die includes a first insulation layer on the metallization structure;
the metal layer is a first metal layer; and
the metallization structure includes a second metal layer; and
the method further comprising:
forming a first opening through the first insulation layer to the first metal layer and a second opening through the first insulation layer to the second metal layer; and
forming a second insulation layer on the first insulation layer, the second insulation layer having a third opening, the third opening exposing:
the first metal layer exposed through the first opening;
the second metal layer exposed through the second opening; and
a surface of the first insulation layer that overlaps with the transistor and between the first opening and the second opening, wherein the die-package interconnect is formed at least in part in the first opening, the second opening, and the third opening.

16. The method of claim 13, wherein the die includes a first insulation layer on the metallization structure, the method further comprising:
forming a first opening through the first insulation layer to the metal layer; and
forming a second insulation layer on the first insulation layer, the second insulation layer having a second opening, the second opening exposing the metal layer exposed through the first opening and exposing a surface of the first insulation layer that overlaps with the transistor, wherein the die-package interconnect is formed at least in part in the first opening and the second opening.

17. The method of claim 13, wherein the die includes a first insulation layer on the metallization structure, the method further comprising:
forming a second insulation layer on the first insulation layer, the second insulation layer having an opening, the opening exposing a surface of the first insulation layer that overlaps with the transistor, wherein the die-package interconnect is formed at least in part in the opening.

18. An apparatus comprising:
a packaged semiconductor device comprising:
a semiconductor substrate including a transistor;
a metallization structure on the semiconductor substrate and including a first metal layer;
a package substrate having a second metal layer;
a die-package interconnect between the metallization structure and the second metal layer, the die-package interconnect overlapping at least part of the transistor; and
one or more insulation layers on the metallization structure, the one or more insulation layers having a first portion having a first thickness and a second portion having a second thickness, the first portion being outside the footprint of the transistor, the second portion being between the die-package interconnect and the at least part of the transistor, the first thickness being larger than the second thickness;
a molding compound encapsulating the semiconductor substrate, the metallization structure, the die-package interconnect, the one or more insulation layers, and at least part of the package substrate; and
a heat sink on a side of the molding compound opposite from the package substrate.

19. The apparatus of claim 18, wherein the die-package interconnect is a bridge die-package interconnect including:
a first vertical portion contacting the first metal layer;
a second vertical portion contacting a third metal layer of the metallization structure; and
a lateral portion extending between the first vertical portion and the second vertical portion, the lateral portion overlapping at least part of the transistor.

20. The apparatus of claim 18, wherein the die-package interconnect is a cantilever die-package interconnect including:
a vertical portion contacting the first metal layer; and
a lateral portion extending from the vertical portion, the lateral portion overlapping at least part of the transistor.
